(19) United States
(12) Patent Application Publication
(10) Pub. No.: US 2025/0087443 A1
(43) Pub. Date: Mar. 13, 2025

(54) NANOFLUIDIC CELL FOR CHARACTERIZATION OF NANO-BUBBLES IN A SIMULATED RESERVOIR

(71) Applicant: Saudi Arabian Oil Company, Dhahran (SA)

(72) Inventors: Dong Kyu Cha, Dhahran (SA); Hassan Alqahtani, Dammam (SA); Mohammed Al Otaibi, Dammam (SA); Subhash Chandrabose Ayirala, Dhahran (SA); Ali Abdallah Al-Yousef, Dhahran (SA)

(21) Appl. No.: 18/462,647

(22) Filed: Sep. 7, 2023

(51) Int. Cl. H01J 37/20; G01N 15/00; H01J 37/28

(52) U.S. Cl. CPC H01J 37/20; G01N 15/00; H01J 37/28; G01N 2015/0011; G03F 7/039; G03F 7/0757; G03F 7/162; G03F 7/2006; H01J 37/3174

(57) ABSTRACT

A system and methods for in situ characterization of nanobubbles in enhanced oil recovery (EOR) are provided. In an exemplary system, a cell includes a metal case including a rectangular shape, wherein the rectangular shape includes five sides and an opening in place of a sixth (top) side, a flow inlet, and a flow outlet. The nanofluidic cell includes a calcite patterned silicon substrate mounted in the metal case, wherein a calcite patterned surface is disposed towards the opening. A transparent lid is mounted over the opening, wherein the transparent lid is in direct contact with calcite structures on the calcite patterned silicon substrate.

### TECHNICAL FIELD

This disclosure relates to characterizing the interactions of nanobubbles with a carbonate well.

### BACKGROUND

Injections of nanobubble solutions into calcite reservoirs for enhanced oil recovery (EOR) in petroleum reservoirs are being studied. However, characterization tools and methods for analyzing the properties and interactions of nanobubbles are needed to enhance and optimize the injection effects.

Microfluidics is used for research of enhanced oil recovery applications because it is considered as an important method to characterize and visualize injected fluid and crude oil interactions. However, conventional microfluidic cells do not have the appropriate size and imaging characteristics to study nanobubbles.

### SUMMARY

An embodiment described herein provides a method for making a nanofluidic cell for in situ characterization of nanobubbles in enhanced oil recovery (EOR). The method includes preparing a silicon substrate, forming a coating of a photoresist over the silicon substrate, drawing a pattern in the photoresist with electron lithography (EL), etching the pattern by removing a portion of the photoresist to form a hollow pattern, depositing calcite in the hollow pattern by atomic layer deposition (ALD), and removing remaining photoresist, forming a calcite patterned silicon substrate. The calcite patterned silicon substrate is packaged in a metal case, wherein the metal case has inlet connections and outlet connections for fluid flow. A transparent window is mounted over the calcite patterned silicon substrate to form the nanofluidic cell.

Another embodiment described herein provides a nanofluidic cell for in situ characterization of nanobubbles in enhanced oil recovery (EOR). The nanofluidic cell includes a metal case comprising a rectangular shape, wherein the rectangular shape includes five sides and an opening in place of a sixth (top) side, a flow inlet, and a flow outlet. The nanofluidic cell includes a calcite patterned silicon substrate mounted in the metal case, wherein a calcite patterned surface is disposed towards the opening. A transparent lid is mounted over the opening, wherein the transparent lid is in direct contact with calcite structures on the calcite patterned silicon substrate.

Another embodiment described herein provides a method for characterizing nanobubbles interactions using a nanofluidic cell. The method includes creating the nanofluidic cell including a metal case comprising a rectangular shape, wherein the rectangular shape includes five sides and an opening in place of a sixth (top) side, a flow inlet, and a flow outlet. The nanofluidic cell includes a calcite patterned silicon substrate mounted in the metal case, wherein a calcite patterned surface is disposed towards the opening. A transparent lid is mounted over the opening, wherein the transparent lid is in direct contact with calcite structures on the calcite patterned silicon substrate. The nanofluidic cell is mounted in a scanning electron microscope (SEM) with the transparent lid facing an electron beam gun and the flow inlet is coupled to a nanobubble generator. Nanobubbles are generated in a solution passing through the nanobubble generator and the solution is fed from the nanobubble generator to the flow inlet of the nanofluidic cell. The nanobubbles are imaged as they pass through the calcite structures on the calcite patterned silicon substrate.

### BRIEF DESCRIPTION OF DRAWINGS

FIG. 1 is a schematic drawing of the fabrication of a calcite patterned silicon substrate.

FIG. 2 is a side cross-section view of a nanofluidic cell.

FIG. 3 is a top schematic view of the operation of the nanofluidic cell.

FIG. 4 is a schematic drawing of a nanofluidic system for using a nanofluidic cell to characterize nanobubbles under dynamic conditions.

FIG. 5 is a process flow diagram of a method for making a nanofluidic cell and using the nanofluidic cell to characterize nanobubbles with an SEM.

### DETAILED DESCRIPTION

Embodiments described herein provide a nanofluidic cell which is used in combination with a sonicator on an inlet line to the nanofluidic cell. This allows the injection of nanobubbles into the nanofluidic cell and the observation of the nanobubbles under dynamic conditions, for example, using a scanning electron microscope (SEM). Further, a method is provided to fabricate the nanosize calcite cylindrical patterned nanofluidic chip by using a combination of electron beam lithography (EL) and atomic layer deposition (ALD). Accordingly, the techniques described herein provide a tool for characterizing the physical properties of nanobubbles and the interaction between fluid-calcite rock and nanobubbles at high resolution.

The conventional methods for fabricating channels in microfluidic chips include glass or silicon etching, photolithography, and molding of polymers. However, it is difficult to fabricate nanosize cylindrical channels due to the resolution of these fabrication methods. Further, forming calcite channels in the nanometer size ranges are more challenging, because of the difficulty of etching natural calcite crystal or thin film-based channels.

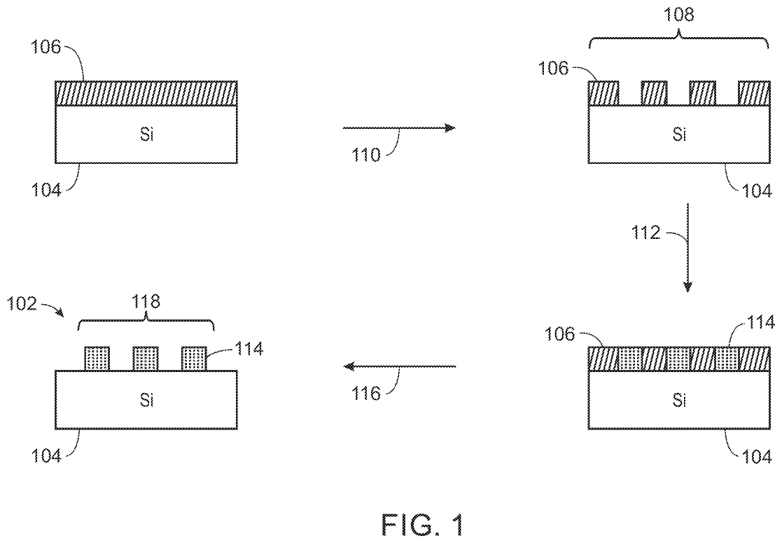

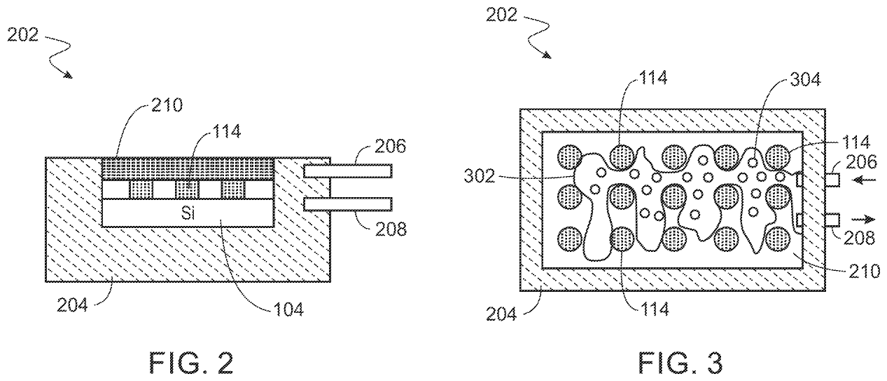

FIG. 1 is a schematic drawing of the fabrication of a calcite patterned silicon substrate 102. The fabrication of the calcite channels is based on a combination of electron lithography (EL) and atomic layer deposition (ALD). To begin, a silicon substrate 104 is prepared, for example, by cutting a larger piece of silicon into the target size. The size of the silicon substrate 104 will depend on the size of the SEM holder and the metal case (FIGS. 2 and 3) as described herein. The silicon substrate 104 together with the metal case is selected to be smaller than the SEM holder.

A photoresist 106, such as polydimethylsiloxane (PDMS) or an epoxy photoresist (SU-8) is applied to the surface of the silicon substrate 104, for example, by spin coating. The thickness of the layer of photoresist 106 will determine the height of calcite channel. Accordingly, it can be selected based on the target size of the nanobubbles.

After the photoresist 106 is applied, a pattern 108 is created, as indicated by arrow 110. The pattern 108 is drawn in an electron lithography (EL) system and the unexposed portions are dissolved by a photoresist developer. The size of the etched hollows or traces of the pattern 108 control the size of the calcite channels. This is selected based upon the expected bubble size. In various embodiments, the size of the calcite channels will be determined by the size of the nanobubbles. In embodiments, the nanobubbles are in a size range of about 50 nm to about 500 nm, or in a size range of about 50 nm to about 100 nm in diameter, or in a size range of about 100 nm to about 200 nm, or in a size range of about 200 nm to about 500 nm, or in a size range of about 300 nm to about 500 nm or in a size range of about 500 nm to about 1 μm.

The traces of the patterns 108 are filled with calcite 114, as indicated by arrow 112, by using ALD with calcite precursor gas. ALD is a surface-controlled layer-by-layer process that results in the deposition of thin films one atomic layer at a time. Layers are formed during reaction cycles by alternately pulsing precursors and reactants and purging with inert gas between each pulse.

In some embodiments, the precursors are Ca(thd)₂ (Hthd=2,2,6,6-tetramethylheptane-3,5-dione), CO₂, and ozone. The pulse parameters for the ALD growth are determined and self-limiting reaction conditions are established between about 200° C. and about 400° C. The calcite layer deposition is formed with CO₂ as the controlling atmosphere in selected runs. The ozone gas has a flow rate of about 500 cm³ min⁻¹ and is produced by feeding pure O₂ into an ozone generator. The applied sublimation temperature for Ca(thd)₂ is about 195° C.

As indicated by arrow 116, the remaining photoresist 106 is removed by a solvent. This leaves a channel structure 118 formed from calcite 114. The silicon substrate 104 with the channel structure 118 formed from the calcite 114 forms the calcite patterned silicon substrate 102.

FIG. 2 is a side cross-section view of a nanofluidic cell 202. Like numbered items are as described with respect to FIG. 1. To make the nanofluidic cell 202, the calcite patterned silicon substrate 102 (FIG. 1) is packaged in a metal case 204. The metal case 204 generally has a rectangular shape, for example, including four sides and a base, or fifth side, on the bottom. In various embodiments, the metal case 204 is aluminum, stainless steel, titanium, or other metals. The metal case 204 can be machined from a single block of metal, for example, by cutting an opening, or slot, into the block of metal. The opening is disposed at the top of the metal case 204. The metal case 204 has a flow inlet 206 for flowing a nanobubbles solution into the nanofluidic cell 202. A flow outlet 208 is used to remove the spent solution from the nanofluidic cell 202 to waste.

The calcite patterned silicon substrate 102 is mounted in the metal case 204, for example, using an adhesive to seal the silicon substrate 104 to the interior of the metal case 204, preventing flow around the calcite patterned silicon substrate 102. A transparent window 210 is mounted over the calcite patterned silicon substrate 102, for example, using an adhesive to seal the transparent window 210 to the metal case 204. The transparent window 210 is generally placed in direct contact with the calcite 114 to prevent flow from bypassing the calcite channels.

The transparent window 210 can be made from any number of materials that have low absorption of electrons and can hold pressure between a fluid and a vacuum, for example, in the sample chamber of the SEM. In some embodiments, the transparent window 210 is silicon nitride (SiN). Further, the transparent window 210 does not have to be optically transparent but may be made from a material that still allows electrons to pass in and out while protecting the contents from the vacuum in the sample chamber. Accordingly, the transparent window 210 can made from graphene, silicon, or strontium titanate (SrTiO₃), among others.

FIG. 3 is a top schematic view of the operation of the nanofluidic cell 202. Like numbered items are as described with respect to previous figures. This view is from the top of the metal case 204, which has the transparent window 210 mounted over an opening. It can be noted that this view may not be visible at optical wavelengths (e.g., 250 nm to 700 nm) depending on the material used for the transparent window 210.

As seen in this view, a brine 302 is injected into the nanofluidic cell 202 through the flow inlet 206. The brine 302 includes nanobubbles 304 as described herein. An SEM can be used image the interaction of the nanobubbles 304 with the calcite 114 of the calcite patterned silicon substrate 102. For example, an electron beam may be directed through the transparent window 210, and electrons reflected back through the transparent window 210 can be used to build the image.

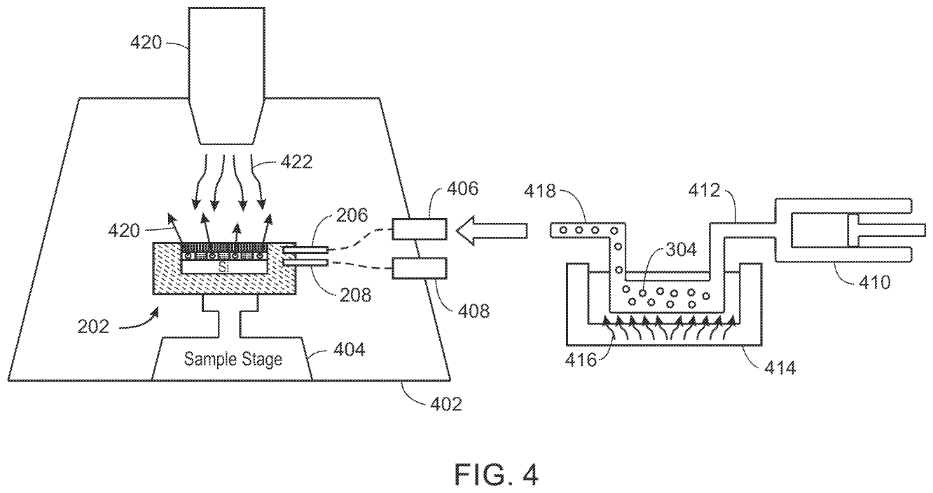

FIG. 4 is a schematic drawing of a nanofluidic system for using a nanofluidic cell 202 to characterize nanobubbles under dynamic conditions. Like numbered items are as described with respect to the previous figures. The nanofluidic cell 202 is mounted in an SEM sample chamber 402 on a sample stage 404. The flow inlet 206 is coupled to a flow inlet 406 on the SEM sample chamber 402. Similarly, the flow outlet 208 is coupled to a flow outlet 408 on the SEM sample chamber 402.

A pump 410 is used to force a brine solution 412 through a sonicator 414. In the sonicator 414, an ultrasonic transducer (not shown) generates ultrasonic waves 416, which form the nanobubbles 304 by forcing gas out of the brine solution 412. The sonicator 414 can be run at any number of conditions, depending on the desired bubble size. For example, for generating nanobubbles in a size range of about 300 to about 500 nm, the frequency is set to about 42 kHz at a power level of about 70 W.

The outlet line 418 from the sonicator 414 is coupled to the flow inlet 406 on the SEM sample chamber 402 to feed the brine solution that includes the nanobubbles 304 to the nanofluidic cell 202. In the SEM sample chamber 402, an electron beam gun 420 fires electrons 422 at the nanofluidic cell 202. The electrons 422 pass through the transparent window of the nanofluidic cell 202 and are reflected back from materials in the nanofluidic cell 202, including, for example, the calcite structures and the nanobubbles. This enables the nanofluidic system to be used to observe and characterize the nanobubbles under dynamic conditions, such as using variations of pressure, bubble size, brine content, and the like.

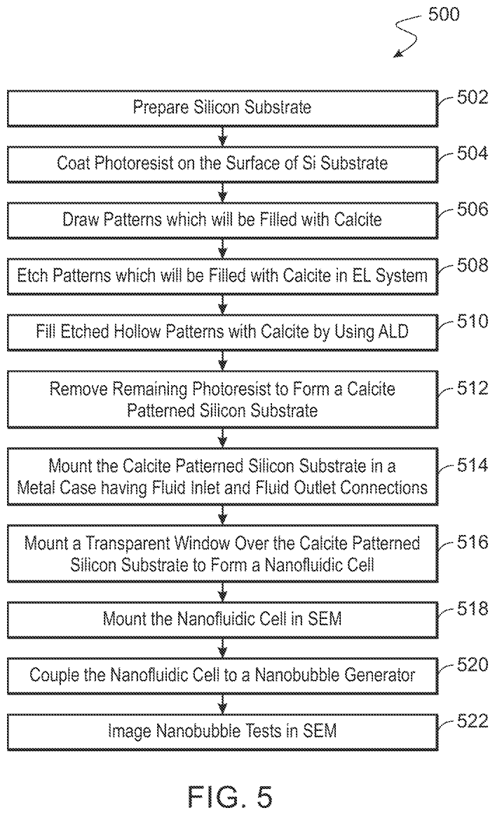

FIG. 5 is a process flow diagram of a method 500 for making a nanofluidic cell and using the nanofluidic cell to characterize nanobubbles with an SEM. The method starts at block 502, with the preparation of the silicon substrate.

At block 504, the photoresist is coated on the surface of the silicon substrate, for example, by spin coating. At block 506, an electron beam is used to draw patterns that will be filled with calcite. Generally, the electron beam cross-links the material of the photoresist, preventing it from being dissolved. At block 508, the patterns are etched by dissolving the portions of the photoresist that were not exposed to the electron beam. This is performed by a photoresist developer. In some embodiments, a positive photoresist may be used, in which areas irradiated by the electron beam are dissolved.

At block 510, atomic layer deposition (ALD) is used to fill the etched hollow patterns with calcite (CaCO₃). This is performed by using calcite precursor gases in an ALD system. At block 512, the remaining photoresist is removed form a calcite patterned silicon substrate. This is performed by solvent dissolution of the cross-linked photoresist.

At block 514, the calcite patterned silicon substrate is mounted in a metal case having fluid inlet and fluid outlet connections as described herein. At block 516, a transparent window is mounted over the calcite patterned silicon substrate to form a nanofluidic cell.

At block 518, the nanofluidic cell is mounted in an SEM, for example, to a sample stage. At block 520, the nanofluidic cell is coupled to a flow line from a nanobubble generator, for example, a sonicator, as described herein. At block 522, nanobubbles tests are performed in the nanofluidic cell, and imaged by the SEM.

### Embodiments

An embodiment described herein provides a method for making a nanofluidic cell for in situ characterization of nanobubbles in enhanced oil recovery (EOR). The method includes preparing a silicon substrate, forming a coating of a photoresist over the silicon substrate, drawing a pattern in the photoresist with electron lithography (EL), etching the pattern by removing a portion of the photoresist to form a hollow pattern, depositing calcite in the hollow pattern by atomic layer deposition (ALD), and removing remaining photoresist, forming a calcite patterned silicon substrate. The calcite patterned silicon substrate is packaged in a metal case, wherein the metal case has inlet connections and outlet connections for fluid flow. A transparent window is mounted over the calcite patterned silicon substrate to form the nanofluidic cell.

In an aspect, combinable with any other aspect, the method includes selecting a size of the silicon substrate based, at least in part, on the size of a holder for a scanning electron micrograph (SEM).

In an aspect, combinable with any other aspect, forming the coating of the photoresist includes applying a coating of polydimethylsiloxane (PDMS) over the silicon substrate.

In an aspect, combinable with any other aspect, forming the coating of the photoresist includes applying a coating of epoxy photoresist (SU-8) over the silicon substrate.

In an aspect, combinable with any other aspect, forming the coating of the photoresist includes spin coating the photoresist over the silicon substrate.

In an aspect, combinable with any other aspect, drawing the pattern includes forming cylindrical shapes of about 50 nm to about 100 nm in diameter.

In an aspect, combinable with any other aspect, etching the pattern includes dissolving the photoresist that has not been exposed to the electron beam.

In an aspect, combinable with any other aspect, depositing calcite in the hollow pattern includes alternating deposition of calcium ions with carbon dioxide.

In an aspect, combinable with any other aspect, removing the remainder of the photoresist includes dissolving photoresist that has been exposed to an electron beam.

In an aspect, combinable with any other aspect, packaging the calcite patterned silicon substrate in the metal case includes placing the calcite patterned silicon substrate in an aluminum, stainless steel, or titanium case.

In an aspect, combinable with any other aspect, mounting the transparent window over the calcite patterned silicon substrate includes mounting a window in direct contact with the calcite patterned silicon.

Another embodiment described herein provides a nanofluidic cell for in situ characterization of nanobubbles in enhanced oil recovery (EOR). The nanofluidic cell includes a metal case including a rectangular shape, wherein the rectangular shape includes five sides and an opening in place of a sixth (top) side, a flow inlet, and a flow outlet. The nanofluidic cell includes a calcite patterned silicon substrate mounted in the metal case, wherein a calcite patterned surface is disposed towards the opening. A transparent lid is mounted over the opening, wherein the transparent lid is in direct contact with calcite structures on the calcite patterned silicon substrate.

In an aspect, combinable with any other aspect, the metal case includes aluminum, stainless steel, or titanium.

In an aspect, combinable with any other aspect, the calcite patterned silicon substrate is sealed into the metal case with an adhesive.

In an aspect, combinable with any other aspect, the transparent lid is silicon nitride.

In an aspect, combinable with any other aspect, the calcite patterned silicon substrate is formed by preparing a silicon substrate, forming a coating of a photoresist over the silicon substrate, drawing a pattern in the photoresist with electron lithography (EL), etching the pattern by removing a portion of the photoresist to form a hollow pattern, depositing calcite in the hollow pattern by atomic layer deposition (ALD), and removing remaining photoresist, forming the calcite patterned silicon substrate.

Another embodiment described herein provides a method for characterizing nanobubbles interactions using a nanofluidic cell. The method includes creating the nanofluidic cell including a metal case including a rectangular shape, wherein the rectangular shape includes five sides and an opening in place of a sixth (top) side, a flow inlet, and a flow outlet. The nanofluidic cell includes a calcite patterned silicon substrate mounted in the metal case, wherein a calcite patterned surface is disposed towards the opening. A transparent lid is mounted over the opening, wherein the transparent lid is in direct contact with calcite structures on the calcite patterned silicon substrate. The nanofluidic cell is mounted in a scanning electron microscope (SEM) with the transparent lid facing an electron beam gun and the flow inlet is coupled to a nanobubble generator. Nanobubbles are generated in a solution passing through the nanobubble generator and the solution is fed from the nanobubble generator to the flow inlet of the nanofluidic cell. The nanobubbles are imaged as they pass through the calcite structures on the calcite patterned silicon substrate.

In an aspect, combinable with any other aspect, generating the nanobubbles includes passing the solution through an ultrasound transducer.

In an aspect, combinable with any other aspect, the ultrasound transducer is operated at 42 kHz at a power level of 70 W.

in an aspect, combinable with any other aspect, the nanobubbles are between about 300 nm and about 500 nm.

Other implementations are also within the scope of the following claims.

What is claimed is:

1. A method for making a nanofluidic cell for in situ characterization of nanobubbles in enhanced oil recovery (EOR), comprising:
preparing a silicon substrate;
forming a coating of a photoresist over the silicon substrate;
drawing a pattern in the photoresist with electron lithography (EL);
etching the pattern by removing a portion of the photoresist to form a hollow pattern;
depositing calcite in the hollow pattern by atomic layer deposition (ALD);
removing remaining photoresist, forming a calcite patterned silicon substrate;
packaging the calcite patterned silicon substrate in a metal case, wherein the metal case has inlet connections and outlet connections for fluid flow; and
mounting a transparent window over the calcite patterned silicon substrate to form the nanofluidic cell.

2. The method of claim 1, comprising selecting a size of the silicon substrate based, at least in part, on the size of a holder for a scanning electron micrograph (SEM).

3. The method of claim 1, wherein forming the coating of the photoresist comprises applying a coating of polydimethylsiloxane (PDMS) over the silicon substrate.

4. The method of claim 1, wherein forming the coating of the photoresist comprises applying a coating of epoxy photoresist (SU-8) over the silicon substrate.

5. The method of claim 1, wherein forming the coating of the photoresist comprises spin coating the photoresist over the silicon substrate.

6. The method of claim 1, wherein drawing the pattern comprises forming cylindrical shapes of about 50 nm to about 100 nm in diameter.

7. The method of claim 1, wherein etching the pattern comprises dissolving the photoresist that has not been exposed to an electron beam.

8. The method of claim 1, wherein depositing calcite in the hollow pattern comprises alternating deposition of calcium ions with carbon dioxide.

9. The method of claim 1, wherein removing the remaining photoresist comprises dissolving photoresist that has been exposed to an electron beam.

10. The method of claim 1, wherein packaging the calcite patterned silicon substrate in the metal case comprises placing the calcite patterned silicon substrate in an aluminum, stainless steel, or titanium case.

11. The method of claim 1, wherein mounting the transparent window over the calcite patterned silicon substrate comprises mounting a window in direct contact with the calcite patterned silicon.

12. A nanofluidic cell for in situ characterization of nanobubbles in enhanced oil recovery (EOR), comprising:
a metal case comprising a rectangular shape, wherein the rectangular shape comprises:
five sides and an opening in place of a sixth (top) side;
a flow inlet; and
a flow outlet;
a calcite patterned silicon substrate mounted in the metal case, wherein a calcite patterned surface is disposed towards the opening; and
a transparent lid mounted over the opening, wherein the transparent lid is in direct contact with calcite structures on the calcite patterned silicon substrate.

13. The nanofluidic cell of claim 12, wherein the metal case comprises aluminum, stainless steel, or titanium.

14. The nanofluidic cell of claim 12, wherein the calcite patterned silicon substrate is sealed into the metal case with an adhesive.

15. The nanofluidic cell of claim 12, wherein the transparent lid is silicon nitride.

16. The nanofluidic cell of claim 12, wherein the calcite patterned silicon substrate is formed by:
preparing a silicon substrate;
forming a coating of a photoresist over the silicon substrate;
drawing a pattern in the photoresist with electron lithography (EL);
etching the pattern by removing a portion of the photoresist to form a hollow pattern;
depositing calcite in the hollow pattern by atomic layer deposition (ALD); and
removing remaining photoresist, forming the calcite patterned silicon substrate.

17. A method for characterizing nanobubbles interactions using a nanofluidic cell, comprising:
creating the nanofluidic cell comprising:
a metal case comprising a rectangular shape, wherein the rectangular shape comprises:
five sides and an opening in place of a sixth (top) side;
a flow inlet; and
a flow outlet;
a calcite patterned silicon substrate mounted in the metal case, wherein a calcite patterned surface is disposed towards the opening; and
a transparent lid mounted over the opening, wherein the transparent lid is in direct contact with calcite structures on the calcite patterned silicon substrate;
mounting the nanofluidic cell in a scanning electron microscope (SEM) with the transparent lid facing an electron beam gun;
coupling the flow inlet to a nanobubble generator;
generating nanobubbles in a solution passing through the nanobubble generator;
feeding the solution from the nanobubble generator to the flow inlet of the nanofluidic cell; and
imaging the nanobubbles as they pass through the calcite structures on the calcite patterned silicon substrate.

18. The method of claim 17, wherein generating the nanobubbles comprises passing the solution through an ultrasound transducer.

19. The method of claim 18, wherein the ultrasound transducer is operated at 42 kHz at a power level of 70 W.

20. The method of claim 17, wherein the nanobubbles are between about 300 nm and about 500 nm.
